(19) United States
(12) Patent Application Publication
(10) Pub. No.: US 2020/0131628 A1
(43) Pub. Date: Apr. 30, 2020

(54) METHOD FOR FORMING MOLYBDENUM FILMS ON A SUBSTRATE

(71) Applicant: ENTEGRIS, INC., Billerica, MA (US)

(72) Inventors: Thomas H. BAUM, New Fairfield, CT (US); Bryan C. HENDRIX, Danbury, CT (US); Philip S.H. CHEN, Bethel, CT (US); Robert WRIGHT, JR., Newtown, CT (US); James WOECKENER, Wappingers Falls, NY (US)

(21) Appl. No.: 16/596,077

(22) Filed: Oct. 8, 2019

Related U.S. Application Data
(60) Provisional application No. 62/749,823, filed on Oct. 24, 2018.

(51) Int. Cl. C23C 16/40; C23C 16/455; H01L 21/02

(52) U.S. Cl. CPC C23C 16/405; C23C 16/45523; H01L 21/0228; H01L 21/02414; H01L 21/02389

(57) ABSTRACT

A process for forming a molybdenum-containing material on a substrate is described, in which the substrate is contacted with molybdenum dioxydichloride (MoO₂Cl₂) vapor under vapor deposition conditions, to deposit the molybdenum-containing material on the substrate. Advantageously, the robust process does not require pre-treatment of the substrate with a nucleating agent. In certain embodiments, the process results in the bulk deposition of molybdenum, e.g., by chemical vapor deposition (CVD) techniques such as pulsed CVD or ALD.

### FIELD OF THE INVENTION

The present invention relates to vapor deposition of molybdenum-containing material. In particular, the present invention relates to the use of molybdenum dioxydichloride (MoO₂Cl₂) as a precursor for such deposition.

### BACKGROUND OF THE INVENTION

In consequence of its characteristics of extremely high melting point, low coefficient of thermal expansion, low resistivity, and high thermal conductivity, molybdenum is increasingly utilized in the manufacture of semiconductor devices, including use in diffusion barriers, electrodes, photomasks, power electronics substrates, low-resistivity gates, and interconnects.

Such utility has motivated efforts to achieve deposition of molybdenum films for such applications that is characterized by high conformality of the deposited film and high deposition rate to accommodate efficient high-volume manufacturing operations. This in turn has informed efforts to develop improved molybdenum source reagents useful in vapor deposition operations, as well as improved process parameters utilizing such reagents.

Molybdenum pentachloride is most commonly used as a molybdenum source for chemical vapor deposition of molybdenum-containing material. However, there remains a need to achieve deposition of molybdenum-containing material with higher deposition rates to accommodate efficient high-volume manufacturing operations.

### SUMMARY OF THE INVENTION

The present invention relates to vapor deposition of molybdenum-containing material, and more specifically to the use of molybdenum dioxydichloride (MoO₂Cl₂) as a source reagent for such vapor deposition, as well as to processes and devices employing molybdenum dioxydichloride (MoO₂Cl₂) as a source reagent.

In one aspect, the invention provides a process for forming a molybdenum-containing material on a substrate, comprising contacting the substrate with molybdenum dioxydichloride (MoO₂Cl₂) vapor under vapor deposition conditions, to deposit the molybdenum-containing material on the substrate.

In various embodiments, the invention relates to a method of forming a molybdenum-containing material on a substrate, comprising depositing molybdenum and/or molybdenum oxide by a vapor deposition process utilizing molybdenum dioxydichloride (MoO₂Cl₂) precursor in conjunction with a reducing compound such as hydrogen, to produce the molybdenum-containing material on the substrate.

Advantageously, in the process of the invention, the molybdenum may be deposited at temperatures of less than about 400° C., which enables the process to be used in the manufacture of logic devices. Such logic devices pose challenges due to compatibility with the existing device structure prior to the molybdenum deposition.

Additionally, the high molybdenum deposition rate reduces tool time and processing cost. We have also found that the process results in reduced titanium nitride etching from exposure to the molybdenum precursor (MoO₂Cl₂). Reduced TiN etching is desired as the cross-sectional area required for conduction in the device can be reduced as extra TiN is rendered less necessary to compensate for any TiN etched during the molybdenum deposition step. Finally, it is desirable to avoid TiN etching as it can result in non-uniform device performance. In one embodiment, the extent of TiN etching is less than about 10 Å per minute.

The films thus formed have less than one percent oxygen, or less than 0.1 percent oxygen, are comprised of greater than 99% molybdenum, and possess conformality greater than 95, greater than 99, or approaching 100% as determined for example by cross-sectional transmission electron microscopy imaging techniques, and resistivity of less than or equal to 20 μΩ·cm at a film thickness of 35 Å.

Other aspects, features and embodiments of the disclosure will be more fully apparent from the ensuing description and appended claims.

### BRIEF DESCRIPTION OF THE DRAWINGS

FIG. 1 is an illustration of film showing aspect ratio and conformality of molybdenum (Mo) film formation on a microelectronic device by the disclosed methods.

FIG. 2 is a comparison of film resistivity versus film thickness for various molybdenum precursors.

FIG. 3 is a plot of titanium nitride (TiN) etch rate versus substrate temperature for molybdenum chemical vapor deposition on 200 Å D-TiN coupons.

FIG. 4 depicts Mo thickness and resistivity as a function of substrate temperature for pulsed CVD Mo deposition

FIG. 5 is a plot of MoOₓ and Mo metal versus hydrogen (H₂) flow rate and chamber pressure. This figure illustrates the importance of and effect of H₂ flow rate on the film's identity, elemental molybdenum metal versus molybdenum oxide.

FIG. 6 is a plot of Mo resistivity in μΩ·cm versus substrate temperature.

FIG. 7 is an illustration of the pulsed chemical vapor deposition process. Pressure is controlled by an automatic throttle valve. The ampoule is pulsed “on” for 1 second to the chamber, then pressurizes during the remaining 59 seconds of the cycle. The pressure in the chamber spikes to a higher pressure value than the pressure set-point, when the ampoule is pulsed open to the chamber.

FIG. 8 is a scanning electron micrograph (SEM) of a cross-sectioned film illustrating Mo deposited film, from MoO₂Cl₂ on a 30 Å TiN coated substrate, using a H₂ co-reactant flow of 3000 sccm.

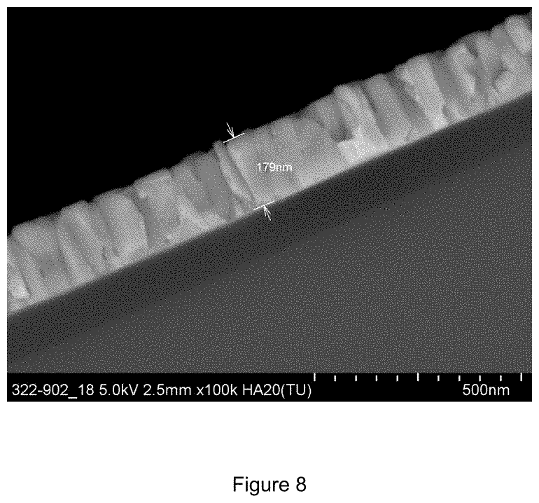

### DETAILED DESCRIPTION OF THE INVENTION

The present invention relates to vapor deposition of molybdenum, and specifically the use of molybdenum dioxydichloride (MoO₂Cl₂) for such deposition, e.g., in the manufacture of semiconductor devices in which molybdenum films of superior conformality and electrical performance properties are desired. In accordance with the present invention molybdenum dioxydichloride (MoO₂Cl₂) has been found in vapor deposition processes such as chemical vapor deposition (CVD) to provide low resistivity, high deposition rate films of a highly conformal character. In one aspect, the invention relates to a process for forming a molybdenum-containing material on a substrate, comprising contacting the substrate with molybdenum dioxydichloride (MoO₂Cl₂) vapor under vapor deposition conditions, to deposit the molybdenum-containing material on the substrate.

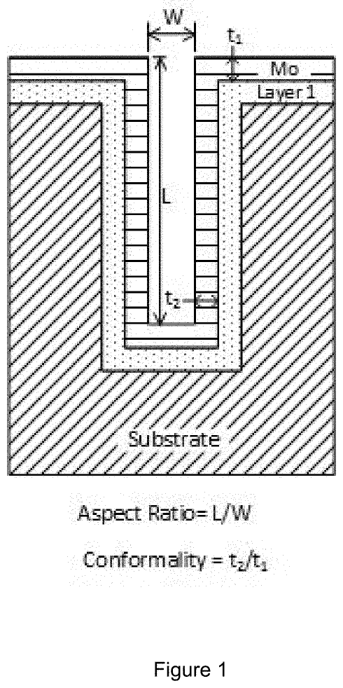

In various embodiments of the invention, the use of molybdenum dioxydichloride (MoO₂Cl₂) as a precursor for vapor deposition of molybdenum-containing material on substrates can provide a high extent of conformality (t₂/t₁ as shown in FIG. 1), approaching 100% conformality, as determined by cross-sectional transmission electron microscopy imaging techniques (See FIG. 1). Advantageously, deposition of molybdenum dioxydichloride (MoO₂Cl₂) can proceed at higher rates than deposition with molybdenum pentachloride (MoCl₅). In the case of 3D NAND structures, MoO₂Cl₂ requires higher pressure, greater hydrogen flow and lower ampoule temperature than MoOCl₄. Furthermore, despite the presence of oxygen in the structure of molybdenum dioxydichloride (MoO₂Cl₂), the molybdenum-containing material so deposited can have low resistivity and oxygen content.

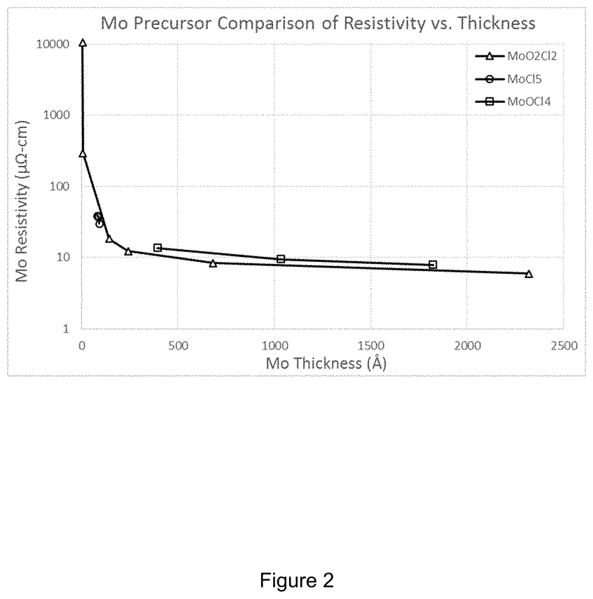

FIG. 2 depicts a plot showing the comparison of film resistivity versus film thickness for three different Mo precursors. In the plot the ampoule is heated to a temperature of 70 degrees C. and the films were deposited onto a silicon substrate coating with a TiN layer.

In certain embodiments of the invention, the precursor can deposited using pulsed vapor deposition conditions. It has been found that this can improve step coverage of the deposition. Suitably the “pulse” and “purge” time of pulsed deposition may each independently be in the range of from 1 to 120 seconds, 1 to 60 seconds, or 1 to 20 seconds, depending on the substrate structure and reactor design.

In various embodiments, the vapor conditions are selected such that the deposited molybdenum-containing material has a resistivity of less than 100 μΩ·cm, less than 50 μΩ·cm, at most 20 μΩ·cm, optionally at most 15-20 μΩ·cm and in other embodiments as low as 8 μΩ·cm.

The molybdenum-containing material may be deposited at a (substrate) temperature in the range of from 350° C. to 750° C., or in the range of from 300° C. to 600° C., or in the range of from 300° C. to 575° C.

In various embodiments, the vapor deposition conditions comprise an inert atmosphere, save for the optional presence of a reducing agent such as hydrogen. In certain embodiments, the molybdenum dioxydichloride (MoO₂Cl₂) vapor may be deposited in the substantial absence of other metal vapors.

The process of the present invention may comprise volatilizing molybdenum dioxydichloride (MoO₂Cl₂) to form the molybdenum dioxydichloride (MoO₂Cl₂) vapor for the vapor deposition operation. The vapor deposition conditions may be of any suitable type, and may for example comprise a reducing ambient (vapor) such as hydrogen gas so that the molybdenum-containing material comprises elemental molybdenum material in the deposited film. The molybdenum-containing material so deposited may comprise, or alternatively consist, or consist essentially of, elemental molybdenum, or molybdenum oxide, or other molybdenum-containing material. Depending on the level of reducing agent, e.g., hydrogen concentration, it is possible to preferentially deposit greater proportions of elemental molybdenum versus molybdenum oxide.

Additional advantage of the invention is that the high molybdenum deposition rate reduces tool time and processing cost. As such, the process results in reduced titanium nitride etching from exposure to the molybdenum precursor (MoO₂Cl₂). It is found that across all substrate temperature ranges tested, etching of TiN substrates was less than 5 Å.

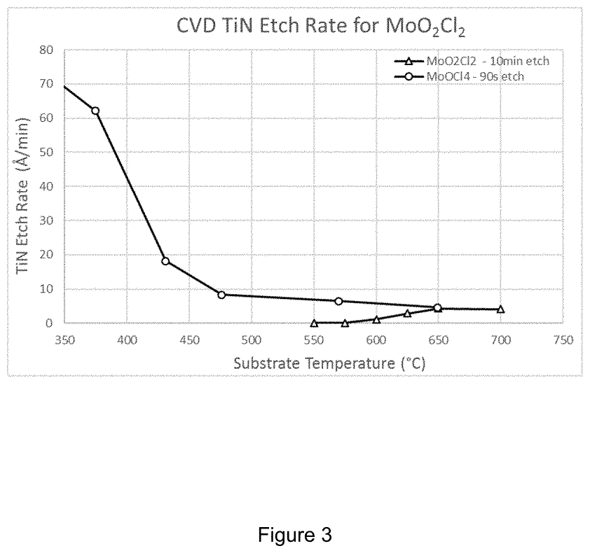

In one aspect of the invention, FIG. 3 shows the comparison of the TiN etch rate for MoOCl₄ and MoO₂Cl₂ precursors deposited as a function of substrate temperature. As shown by FIG. 3, MoO₂Cl₂ displays lower etch rates of TiN when compared to MoOCl₄. The deposition conditions used in the plot for FIG. 3 were Tₐₘₚₒᵤₗₑ=60° C. (temperature of the ampoule), 200 A TiN substrate, Argon (Ar) flow rate=50 sccm, H₂ flow rate=4000 sccm for MoO₂Cl₂ and H₂ flow=2000 sccm for MoOCl₄.

In other embodiments of the invention, the substrate utilized in the process described can be of any suitable type, and may for example comprise a semiconductor device substrate, e.g., a silicon substrate, a silicon dioxide substrate, or other silicon-based substrate. In various embodiments, the substrate may comprise one or more metallic or dielectric substrates, for example, TiN, Mo, MoC, SiO₂, W, SiN, WCN, Al₂O₃, AlN, ZrO₂, HfO₂, SiO₂, lanthanum oxide (La₂O₃), tantalum nitride (TaN), ruthenium oxide (RuO₂), iridium oxide (IrO₂), niobium oxide (Nb₂O₃), and yttrium oxide (Y₂O₃).

In certain embodiments, for example in the case of an oxide substrate such as silicon dioxide, or alternatively a silicon or polysilicon substrate, the substrate may be processed or fabricated to include a barrier layer thereon, e.g. titanium nitride, for subsequently deposited material.

In one embodiment, the molybdenum-containing layer deposited on the substrate surface may for example be formed by pulsed chemical vapor deposition (CVD) or atomic layer deposition (ALD) or other vapor deposition technique, without the prior formation of a nucleation layer and thus directly with molybdenum dioxydichloride (MoO₂Cl₂) vapor. The respective molybdenum dioxydichloride (MoO₂Cl₂) vapor contacting steps may be carried out alternatingly and repetitively for as many cycles as are desired to form the desired thickness of the molybdenum film. In various embodiments, the contact of the substrate (e.g., titanium nitride) layer with molybdenum dioxydichloride (MoO₂Cl₂) vapor is conducted at temperature as low as 350°, and in other embodiments, in a range of from 300° C. to 750° C., as defined herein for (MoO₂Cl₂) vapor deposition.

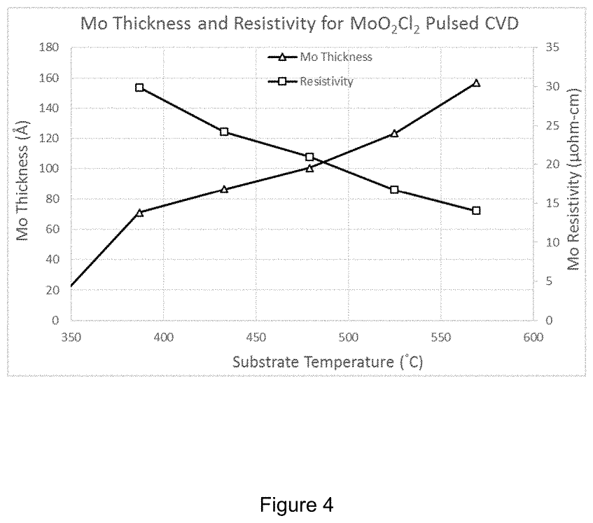

FIG. 4 shows a plot of deposited Mo film thickness and film resistivity measured as a function of substrate temperature for the pulsed CVD deposition of Mo from MoO2Cl2. The deposition conditions in FIG. 4 used were 100 cycles of pulsing (1 s on/59 s off), at 80 T, at flow rate=50 sccm and H₂ flow rate=4000 sccm.

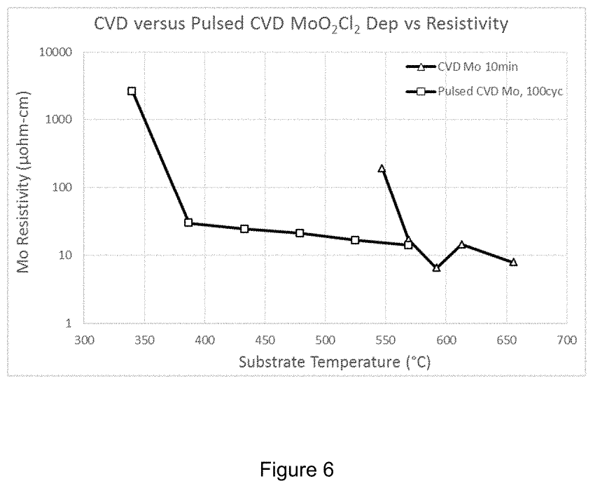

Furthermore, FIG. 6 depicts a plot showing Mo film resistivity versus substrate temperature for comparing both CVD and pulsed deposition of Mo from MoO₂Cl₂. Mo film quality, as evidenced by film resistivity, degrades below T_{sub}=570° C. for CVD, while the pulsed CVD process affords good Mo films at T_{sub}=−380° C. Referring to FIG. 6, deposition conditions used were Tₐₘₚₒᵤₗₑ=60° C., 200 A TiN thickness, pressure=80 T, Ar flow rate=50 sccm, H₂ flow rate=4000 sccm, pulsed deposition sequence of precursor on for 1 s, off for 59 seconds. It is noted that Mo film thickness is lower at lower temperatures.

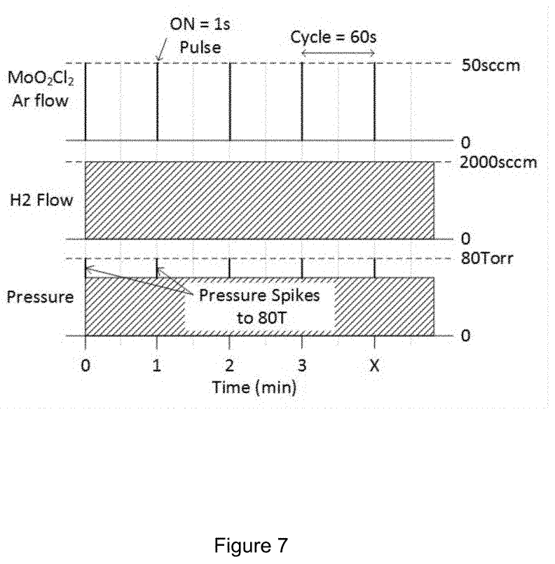

Furthermore, FIG. 7 provides a schematic representation of the pulsed CVD method and timing sequence used for Mo deposition from MoO₂Cl₂ showing precursor introduction pulses, H₂ flows and pressure. Pressure spikes >60 T base pressure are noted when the precursor is pulsed into the reactor chamber.

With molybdenum dioxydichloride (MoO₂Cl₂) vapor, the molybdenum-containing material can be deposited directly onto the substrate, to form a bulk deposit of elemental molybdenum or molybdenum oxide or other molybdenum-containing compound or composition. The concentration of H₂ is critical towards the formation of molybdenum metal or oxide, as greater than four molar equivalents or an excess of H₂ is required for metal formation. Less than four (4) molar equivalents of H₂ will result in the formation of varying amounts of an oxide of molybdenum, and thus will require further exposure to H₂ in order to reduce the molbybdenum oxide thus formed.

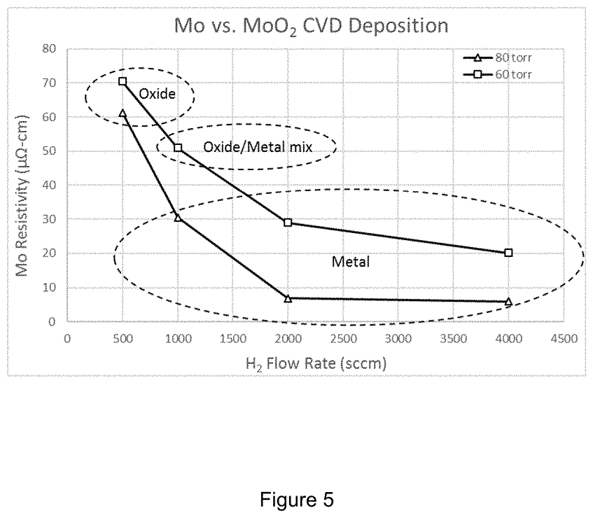

FIG. 5 depicts plot representing the measured film resistivity and film composition, as verified by x-ray diffraction, for films deposited from MoO₂Cl₂ as a function of H₂ flow rate for two reactor pressures (60 and 80 T). As shown by FIG. 5, the formation of MoOx and Mo (metal) is strongly dependent upon the H₂ flow rate. The deposition conditions used in FIG. 5 were Tₐₘₚₒᵤₗₑ=60° C., 40 A TiN thickness, Ar flow rate=50 sccm, T_{sub}=656° C. for 10 minutes.

In various embodiments, the molybdenum-containing material is deposited on the surface at temperature in a range of from 300° C. to 750° C. or another range as defined hereinabove for (MoO₂Cl₂) vapor deposition. The process may be carried out so that the vapor deposition conditions produce deposition of elemental molybdenum as the molybdenum-containing material on the substrate. The vapor deposition conditions may be of any suitable character, and may for example comprise presence of hydrogen or other reducing gas, to form a bulk layer of elemental molybdenum on the substrate.

More generally, the broad method of forming a molybdenum-containing material on a substrate in accordance with the present disclosure may comprise vapor deposition conditions comprising presence of hydrogen or other reducing gas. The molybdenum-containing material may be deposited on the barrier layer or surface in the presence or absence of hydrogen. For example, the barrier layer may be constituted by titanium nitride, and the titanium nitride layer may be contacted with molybdenum dioxydichloride (MoO₂Cl₂) vapor in the presence of hydrogen.

It will be appreciated that the method of the present disclosure may be carried out in numerous alternative ways, and under a wide variety of process conditions. The process of the invention may for example be carried out in a process for making a semiconductor device on the substrate. The semiconductor device may be of any suitable type, and may for example comprise a DRAM device, 3-D NAND device, or other device or device integrated structure. In various embodiments, the substrate may comprise a via in which the molybdenum-containing material is deposited. The device may, for example, have an aspect ratio (L/W) of depth to lateral dimension that is in a range of from 2:1 to 40:1 (See FIG. 1).

The process chemistry for depositing molybdenum-containing material in accordance with the present disclosure may include deposition of elemental molybdenum, Mo(0), by the reaction 2MoO₂Cl₂+6H₂→2Mo+4HCl+4H₂O. Intermediary reactions may be present and are well known in the art.

The molybdenum-containing material deposited in accordance with the method of the present invention may be characterized by any appropriate evaluation metrics and parameters, such as deposition rate of the molybdenum-containing material, film resistivity of the deposited molybdenum-containing material, film morphology of the deposited molybdenum-containing material, film stress of the deposited molybdenum-containing material, step coverage of the material, and the process window or process envelope of appropriate process conditions. Any appropriate evaluation metrics and parameters may be employed, to characterize the deposited material and correlate same to specific process conditions, to enable mass production of corresponding semiconductor products. Advantageously, the process of the invention is capable of depositing a film of high purity molybdenum onto a semiconductor device. Accordingly, in a further aspect, the invention provides a semiconductor device having a molybdenum film deposited thereon, wherein said film comprises greater than 99% molybdenum.

In certain embodiments, the disclosure relates to a method of forming a molybdenum-containing material on a substrate, comprising depositing molybdenum on the substrate surface by a chemical vapor deposition (CVD) process utilizing molybdenum dioxydichloride (MoO₂Cl₂) precursor, to produce the molybdenum-containing material on the substrate.

Such process may be carried out in any suitable manner as variously described herein. In specific embodiments, such method may be conducted with a vapor deposition process comprising chemical vapor deposition, e.g., pulsed chemical vapor deposition. The method may be carried out so that the resulting molybdenum-containing material is composed essentially of elemental molybdenum, and in various embodiments the molybdenum may be deposited on the substrate surface in the presence of hydrogen or other suitable reducing gas. In other embodiments of the invention, the MoO₂Cl₂ and reducing gas may be pulsed sequentially to deposit he molybdenum film on pulsing with the pulse sequence being optimized for film conformality and film resistivity. The method may be carried out in the manufacture of a semiconductor device product, such as a DRAM device, or a 3-D NAND and logic device.

Generally, the methods of the present disclosure for forming molybdenum-containing material on a substrate may be carried out to achieve deposition of the molybdenum-containing material at high levels of step coverage, e.g., step coverage of from 75% to 100%.

The molybdenum-containing films formed on substrates exhibit good adhesion properties. In one embodiment, the deposition is conducted without pretreatment of the silicon dioxide substrate and the resulting molybdenum film exhibits an adhesion of >95% by ASTM D 3359-02—Standard Test Methods for Measuring Adhesion by Tape Test.

This invention can be further illustrated by the following examples of preferred embodiments thereof, although it will be understood that these examples are included merely for purposes of illustration and are not intended to limit the scope of the invention unless otherwise specifically indicated.

### EXPERIMENTAL SECTION

### General Procedure:

A semiconductor device may be fabricated by the following sequence of process steps on the substrate comprising the titanium nitride barrier layer on the silicon dioxide base layer.
Step 1: Purging the deposition chamber;
Step 2: contacting the barrier layer (TiN layer) of the substrate with a pulse of molybdenum dioxydichloride (MoO₂Cl₂) vapor, in the presence of hydrogen (H₂) or argon (Ar) or Inert gas, for example at temperature on the order of 500° C.;
Step 3; The system is purged under H₂ or inert gas (e.g., Ar) to allow for complete reaction of the MoO₂Cl₂ precursor with the H₂ co-reactant and substrate.
Step 4: repeating Steps 1-3 (optional) to form a molybdenum film layer of desired characteristics.

### Example 1

Process Parameters in the following ranges;
1) Precursor flow in the range of 1 standard cubic centimeters per minute (sccm) to 1000 sccm.
2) Inert precursor carrier gas flow in the range of 1 to 10000 sccm
3) H₂ co-reactant flow in the range of 25 sccm to 25000 sccm
4) Pressure in the range of 0.1 T to 250 T
5) Substrate temperature in the range of 300 to 1000 C
6) Pulsed CVD cycle times including a) Precursor pulse “ON” time from 0.1 seconds to 120 seconds, b) Precursor pulse “OFF” time from 1 second to 120 second
7) Deposition cycles from 1 to 10000 cycles

### Example 1 for Al₂O₃ Substrate

Pulsed CVD Mo deposition at a substrate temperature of 400° to 700° C., for 20 to 200 deposition cycles of 1 sec “ON” and 39 sec “OFF”, at 4000 sccm (4 lpm) H₂ flow, Chamber pressure of 80 T; Mo metal deposition rates were 0.1 to 5 Angstroms/cycle with resistivities of 10 to 33 μΩ-cm. Al₂O₃ etching of 2-3 Angstroms were measured mostly in part due to loss of XRF signal in the Mo top layer and most likely not due to actual etching of the Al₂O₃

### Example 2 for SiO₂ Substrate

Pulsed CVD Mo deposition at a substrate temperature of 450° to 700° C., for 20 to 200 deposition cycles of 1 second “ON” and 39 seconds “OFF”, at 4 lpm H₂ flow, Chamber pressure of 80 T; Mo metal deposition rates were 0.4 to 6 Angstroms/cycle with resistivities of 10 to 70 μΩ-cm. SiO₂ etch rates were not measured.

### Example 3 for TiN Substrate

Pulsed CVD Mo deposition at a substrate temperature of 360° to 700° C., for 25 to 200 deposition cycles of 1 second “ON” and 39 seconds “OFF”, at 4 lpm H₂ flow, Chamber pressure of 80 T; Mo metal deposition rates were 0.2 to 2.8 Angstroms/cycle with resistivities of 12 to 1200 μΩ-cm. TiN etching of 0 to 2.3 Angstroms was measured.

We claim:

1. A process for forming a molybdenum-containing material on a substrate, comprising contacting the substrate with molybdenum dioxydichloride (MoO₂Cl₂) vapor under vapor deposition conditions, to deposit the molybdenum-containing material on the substrate.

2. The process of claim 1, wherein the substrate is chosen from titanium nitride (TiN), tantalum nitride (TaN), aluminum nitride (AlN), aluminum oxide (Al₂O₃), zirconium oxide (ZrO₂), hafnium oxide (HfO₂), silicon dioxide (SiO₂), silicon nitride (SiN), lanthanum oxide (La₂O₃), ruthenium oxide (RuO₂), iridium oxide (IrO₂), niobium oxide (Nb₂O₅), and yttrium oxide (Y₂O₃).

3. The process of claim 2, wherein the substrate is titanium nitride.

4. The process of claim 2, wherein the substrate is aluminum oxide.

5. The process of claim 2, wherein the substrate is silicon dioxide.

6. The process of claim 2, wherein the substrate is silicon nitride.

7. The process of claim 3, wherein the contact of the titanium nitride substrate with molybdenum dioxydichloride vapor is conducted at a temperature from about 350° C. to about 750° C.

8. The process of claim 4, wherein the contact of the aluminum oxide substrate with molybdenum dioxydichloride vapor is conducted at a temperature of from about 350° C. to about 750° C.

9. The process of claim 5, wherein the contact of the silicon dioxide substrate with molybdenum dioxydichloride vapor is conducted at a temperature of from about 350° C. to about 750° C.

10. The process of claim 1, wherein the vapor deposition conditions are selected such that the deposited molybdenum-containing material has a resistivity of less than about 50 μΩ·cm.

11. The process of claim 1, wherein the vapor deposition conditions are selected such that the deposited molybdenum-containing material has a resistivity of less than about 20 μΩ·cm.

12. The process of claim 1, wherein the vapor deposition conditions further comprises H₂.

13. The process of claim 12, wherein the vapor deposition conditions further comprises H₂ at a concentration of greater than or equal to 4 molar equivalents.

14. The process of claim 1, wherein the vapor deposition conditions are pulsed chemical vapor deposition conditions.

15. The process of claim 1, wherein the molybdenum containing material is deposited on the substrate at step coverage of from 75% to 100%.

16. The process of claim 3, wherein titanium nitride etching is less than about 10 angstroms per minute.

17. The process of claim 4, wherein the deposition is conducted without pretreatment of the aluminum oxide substrate.

18. The process of claim 5, wherein the deposition is conducted without pretreatment of the silicon dioxide substrate and the resulting molybdenum film exhibits an adhesion of >95% by ASTM D 3359-02—Standard Test Methods for Measuring Adhesion by Tape Test.

19. The process of claim 1, wherein the process is conducted without a pre-nucleation step.

20. A semiconductor device having a molybdenum film deposited thereon, wherein said film comprises greater than 99% molybdenum, less than 1% oxygen, conformality of greater than 99%, and a resistivity of less than 20 μΩ·cm when measured on a film having a thickness of 35 Å.
